(19) United States
(12) Patent Application Publication
(10) Pub. No.: US 2026/0352218 A1
(43) Pub. Date: Nov. 5, 2026

(54) OSCILLATOR SELF-CALIBRATION

(71) Applicant: Texas Instruments Incorporated, Dallas, TX (US)

(72) Inventors: Aswin R, Bangalore (IN); Aditya Jonnalagadda, Bangalore (IN); Nilesh Upadhye, Chandrapur (IN)

(21) Appl. No.: 19/194,582

(22) Filed: Apr. 30, 2025

(51) Int. Cl. H03L 7/099

(52) U.S. Cl. CPC H03L 7/0995

(57) ABSTRACT

An electronic device includes a first oscillator having a trim input and a first oscillator output, a second oscillator having a second oscillator output, a memory that stores calibration data, and a calibration circuit coupled to the first and second oscillator outputs and configured to automatically calibrate the first oscillator using the second oscillator based on the calibration data. A method includes performing a first calibration of a first oscillator of an electronic device using a second oscillator of the electronic device and storing calibration data from the first calibration in a memory of the electronic device.

### BACKGROUND

Electronic device oscillators are used to provide a clock signal for internal and/or external clocked circuits. The oscillator can be trimmed to calibrate the frequency of the clock signal at final test after packaging, for example, to adjust for the impact of package stress. However, calibration during manufacturing using external sources requires connection to the device and is expensive in terms of production time and precise external tester clock equipment. Moreover, electronic device oscillators can suffer from effects of lifetime ageing of components leading to clock output frequency drift over time, but field calibration using an external clock reference is impractical.

### SUMMARY

In one aspect, an electronic device includes a first oscillator having a trim input and a first oscillator output, a second oscillator having a second oscillator output, a memory that stores calibration data, and a calibration circuit coupled to the first and second oscillator outputs and configured to automatically calibrate the first oscillator using the second oscillator based on the calibration data.

In another aspect, an electronic device includes a first oscillator having a first trim input, a second trim input and a first oscillator output, and a second oscillator having a second oscillator output, a calibration circuit coupled to the first and second oscillator outputs, a trim controller having a first trim output coupled to the first trim input, and a second trim output coupled to the second trim input, and a memory that stores calibration data from a factory calibration of the first oscillator.

In a further aspect, a method includes performing a first calibration of a first oscillator of an electronic device using a second oscillator of the electronic device and storing calibration data from the first calibration in a memory of the electronic device.

In another aspect, a system includes a clocked circuit having a clock input and an electronic device, the electronic device including a first oscillator having a first trim input, a second trim input and a first oscillator output coupled to the clock input of the clocked circuit, a second oscillator having a second oscillator output, a calibration circuit coupled to the first and second oscillator outputs, a trim controller having a first trim output coupled to the first trim input, and a second trim output coupled to the second trim input, and a memory that stores calibration data from a factory calibration of the first oscillator.

### BRIEF DESCRIPTION OF THE DRAWINGS

FIG. 1 is a system view of an electronic device with a first oscillator providing a clock signal to a clocked circuit and a second oscillator used to calibrate the first oscillator.

FIG. 1A is a schematic diagram of an example implementation of the electronic device of FIG. 1.

FIG. 2 is a flow diagram of an example method of calibrating an oscillator of an electronic device.

FIG. 3 is a graph showing example frequency slope trim values as a function of temperature.

FIG. 4 is a graph showing example frequency magnitude trim values as a function of temperature.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, sides, etc., for ease of description in connection with a particular drawing, where such are not to be construed as limiting with respect to the claims. Various structures and methods of the present disclosure may be beneficially applied to an electronic apparatus such as an integrated circuit and to manufacturing electronic devices and/or systems. While such examples may be expected to provide various improvements, no particular result is a requirement of the present disclosure unless explicitly recited in a particular claim.

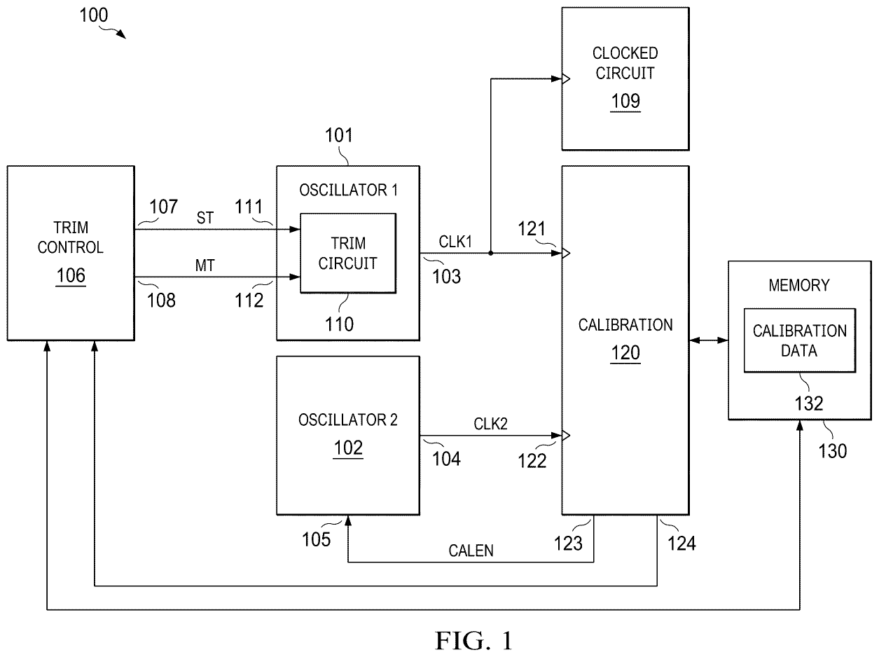

FIG. 1 shows a system with an electronic device 100 that includes a first oscillator 101 and a second oscillator 102. The electronic device 100 is configured to perform self-calibration of the first oscillator 101 during production by on-chip oscillator frequency measurement using the second oscillator 102 to detect and correct component degradation after package stress during final production testing. This feature eliminates the need for expensive external calibration sources and the added time and cost of connecting production electronic devices to external equipment during manufacturing. The electronic device 100 is also configured to perform self-calibration of the first oscillator 101 in field operation such as during device power up. This further allows the electronic device 102 compensate for any effects of ageing related frequency drifts in the circuitry of the first oscillator 101 and help system performance over time. The first oscillator 101 has a first oscillator output 103 that provides a first clock output signal CLK1. The second oscillator 102 has a second oscillator output 104 that provides a second clock output signal CLK2. In certain examples, the second oscillator 102 has an enable input 105 that allows the second oscillator 102 to be automatically turned on or off, although not a requirement of all possible implementations.

The electronic device 100 includes a trim controller 106 that is coupled to the first oscillator 101 for setting one or more trim values used in calibrating the first oscillator 101. The trim controller 106 in one example includes a first trim output 107 coupled to provide a first trim value ST to the first oscillator 101, and a second trim output 108 coupled to provide a second trim value MT to the first oscillator 101. In this example, the trim controller 106 provides the values ST and MT to adjust the slope and magnitude of the frequency of the first clock output signal CLK1. In another example, the trim controller 106 has a single trim output to provide a trim value to the first oscillator 101, for example, to adjust a frequency slope, a frequency magnitude, or other parameter affecting the output frequency of the first oscillator 101. In other examples, the trim controller 106 can provide more than two trim values to the first oscillator 101 for calibrating the frequency of the first clock output signal CLK1.

FIG. 1 shows a system view of the electronic device 100 with the first oscillator output 103 coupled to provide the first clock output signal CLK1 to a clock input of a clocked circuit 109. The clocked circuit 109 can be any electronic circuit that uses (e.g., operates according to) a received clock signal. Suitable examples include a microprocessor, memory, digital logic, etc. The clocked circuit 109 in one example is integrated in the electronic device 100. In another example, the clocked circuit 109 is an external device, such as an integrated circuit with the clock input connected to the first oscillator output 103 by signal trace routing of a host circuit board (not shown). In these or another example, the first oscillator output 103 can be connected to provide the first clock output signal CLK1 to multiple clocked circuits, which can be integrated into the electronic device 100 and/or external to the electronic device 100, or combinations of internal and external clocked circuits.

The first oscillator 101 in one example includes a trim circuit 110 having a first trim input 111 to trim a frequency slope of the first oscillator 101 and a second trim input to trim a frequency magnitude of the first oscillator 101. In this example, the first trim output 107 of the trim controller 106 is coupled to provide a first trim value ST to the first trim input 111 of the first oscillator 101, and the second trim output 108 is coupled to provide a second trim value MT to the second trim input 112 of the first oscillator 101. In operation, the trim circuit 110 uses the first trim value ST in order to set or adjust a frequency slope of the first oscillator 101. The trim circuit 110 uses the second trim value MT to set or adjust a frequency magnitude of the first oscillator 101.

The electronic device 100 includes a calibration circuit 120 with a first input 121 coupled to the first oscillator output 103, as well as a second input 122 coupled to the second oscillator output 104. The calibration circuit 120 in one example has a calibration enable output 123 coupled to the enable input 105 of the second oscillator 102, although not a requirement of all possible implementations. In operation, the calibration circuit 120 provides a calibration enable signal CALEN to the enable input 105 in order to selectively power up or power down (e.g., turn on or turn off) the second oscillator 102. In another example, the calibration enable output 123 can be omitted. The calibration circuit 120 in one example includes a control output 124 coupled to an input of the trim control circuit 106. In one implementation, the control output 124 provides calibration data to the trim control circuit 106 to facilitate calibration operations as described further hereinafter.

The electronic device 100 also includes a memory 130 that stores calibration data 132. In one example, the memory 130 is a non-volatile electronic memory that retains the stored calibration data 132 while the electronic device 100 is powered down. In operation, the calibration circuit 120 is configured to automatically calibrate the first oscillator 101 using the second oscillator 102 based on the calibration data 132. In one example, the calibration data 132 includes one or more values from a factory calibration of the first oscillator 101. In one example, the memory 130 is operatively coupled with the trim controller 106 and with the calibration circuit 120. In one implementation, the trim controller 106 and/or the calibration circuit 120 can store data (e.g., values, flags, or other information, etc.) to the memory 130, for example, using a write operation, and the trim controller 106 and/or the calibration circuit 120 can obtain data from the memory 130, for example, using a read operation. In another implementation, the calibration circuit 120 can read and write data from and move data to the memory 130, and the calibration circuit 120 provides data to the trim controller 106 based on the data from the memory 130 to implement one or more functions associated with calibrating the first oscillator 101.

FIG. 1A shows an example implementation of the electronic device of FIG. 1. In this example, the first oscillator 101 includes a capacitor 117 with a capacitance C connected in parallel with a switch 118. The first oscillator 101 has a comparator 119 that generates the first clock output signal CLK1 having a first oscillator period TOSC1 based on the voltage of the capacitor 117. A first terminal of the capacitor 117 is connected to a first input of the comparator 119, a second terminal of the capacitor 117 is connected to a ground reference node, and a second input of the comparator 119 is connected to a reference voltage VREF. The output of the comparator 119 is connected to the first oscillator output 103 and is used to control the switch 118 to discharge the capacitor 117. The capacitor 117 is charged by a current I from a current mirror circuit 113 of the trim circuit 110 and the comparator 119 activates the switch 118 in response to the capacitor voltage rising to the level of the reference voltage VREF.

The trim circuit 110 in the example of FIG. 1A is a current source trim circuit 110 with an output coupled to provide the charging current I to the first terminal of the capacitor 117. The trim circuit 110 includes the current mirror circuit 113 with first and second transistors (e.g., p-channel) coupled to a positive voltage V+, a transistor 114 with a drain coupled to a first transistor of the current mirror 113, a source coupled to a variable resistor 115, and a gate coupled to an output of an amplifier 116. An inverting input (e.g., labeled “−”) of the amplifier 116 is coupled to a reference voltage VREF and a noninverting input (e.g., labeled “+”) of the amplifier 116 is coupled to the source of the transistor 114. In operation, the amplifier 116 controls the gate voltage of the transistor 114 to regulate the voltage at the upper or first terminal of the resistor 115 to the reference voltage VREF. The regulation operation of the amplifier 116 regulates the current source current I to an approximately constant value that is generally independent of any variations in the positive voltage V+.

The trim circuit 110 includes the first trim input 111 coupled to set an amplifier gain of the amplifier 116 in order to trim a frequency slope of the first oscillator 101 according to the first trim value ST. In one example, the trim controller 106 provides the first trim value ST as a digital slope trim value to set a resistance value of a feedback resistor (not shown) in a feedback network of the amplifier 116 to set the amplifier gain. The gain of the amplifier 116 controls the gain of the gate signal provided to the transistor 114. The trim circuit 110 has the second trim input 112 to set a resistor value (e.g., resistance R) of the resistor 115 to trim a frequency magnitude of the first oscillator 101. In one example, the trim controller 106 provides the second trim value MT as a digital magnitude trim value to set the resistance value R.

The second oscillator 102 in the example of FIG. 1A is a ring oscillator 140 that includes three CMOS inverters 141, 142, 143 connected with a second input of an AND gate 144 in a loop or ring circuit with an output of the final inverter 143 connected to an input of the AND gate 144. In another example, a different odd number of inverters can be used. The enable input 105 is connected to a first input of the AND gate 144 to allow the calibration circuit 120 to selectively turn the ring oscillator on or off based on the calibration enable signal CALEN at the calibration enable output 123 of the calibration circuit 120. In other examples, a different type of the second oscillator can be used. In operation, when enabled, the second oscillator 102 provides the second clock output signal CLK2 having a second oscillator period TOSC2.

The inverters 141-143 of the second oscillator 102 have power supply rails including a positive rail connected through a first (e.g., P-channel) transistor 145 to a positive supply voltage VDD and a negative rail connected through a second (e.g., N-channel) transistor 148 to the ground reference. In one example, the positive supply voltage VDD is provided by a regulated supply circuit, for example, to help prevent frequency variations associated with supply voltage chances. In one example, the positive supply voltage VDD is supplied from an on-chip low-dropout regulator (LDO, not shown) a reference buffer, etc., as opposed to an unregulated or external supply. The example second oscillator 102 also includes an inverter 146 with an input connected to the enable input 105 and an output connected to the gate of the first transistor 145, as well as a buffer 147 (e.g., non-inverting) with an input connected to the enable input 105 and an output connected to the gate of the transistor 148.

The ageing degradation of the first oscillator 101 in one example is due to thermal ageing of the resistor 115 of the trim circuit 110. In contrast, the degradation of the example second oscillator 102 is largely due to electrical stress resulting in bias temperature instability (BTI) for the inverter cells 141-143 of the ring oscillator 140, which can be addressed by selectively powering the oscillator on only when used for calibrating the first oscillator 101. In one example, the calibration circuit 120 is configured to automatically turn the second oscillator 102 off after calibrating the first oscillator 101, and then to turn the second oscillator 102 on before the next oscillator calibration. This feature provides multiple benefits, including reducing power consumption during normal operation of the electronic device 100 where the second oscillator 102 is not needed. In addition, turning the second oscillator 102 off when not in use for calibrating the first oscillator 101 advantageously mitigates aging or time-based degradation of the output frequency of the second clock output signal CLK2. This facilitates use of the second oscillator 102 in calibrating the first oscillator 101 to compensate for aging effects on the output frequency of the first oscillator 101 using the second clock output signal CLK2 that has not been affected by aging during field use of the electronic device 100.

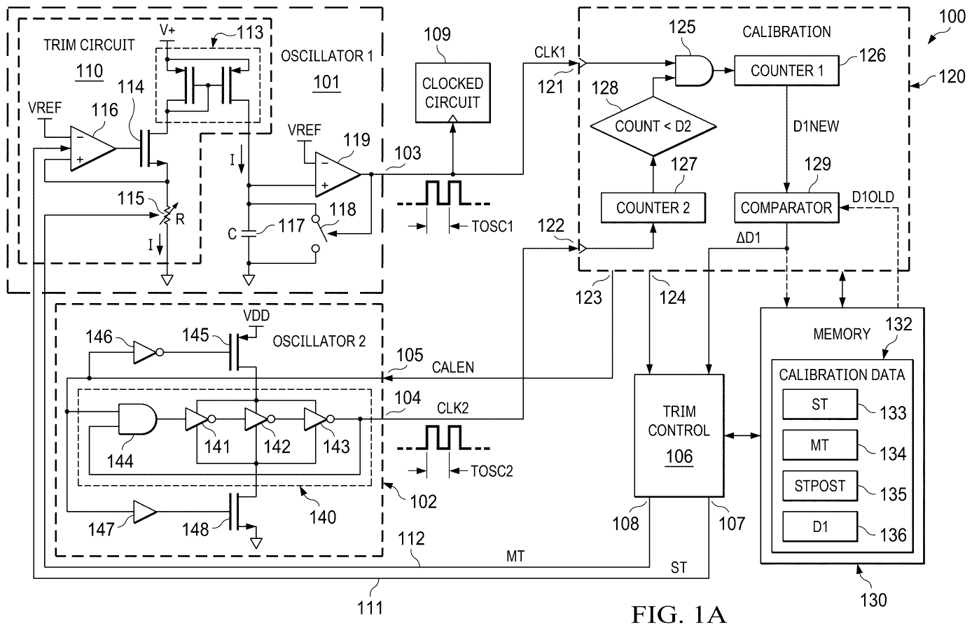

In one example, the calibration circuit 120 is configured to calibrate the first oscillator 101 in response to the electronic device 100 powering up. As illustrated and described further below in connection with FIG. 2, the calibration circuit 120 in this example detects a power up event of the electronic device and turns the second oscillator 102 on in response. The first oscillator 101 is then calibrated using the second oscillator 102, after which the calibration circuit 120 turns the second oscillator 102 off. In this or another example, the calibration circuit 120 can be configured to perform a calibration of the first oscillator 101 in response to a different event, such as receipt of a reset or calibration signal at the end input terminal of the electronic device (not shown). This allows a host system (e.g., a microprocessor of the electronic device 100 or of a host circuit board to which the electronic device 100 is connected) to recalibrate the first oscillator 101 and any desired time. In these or another implementation, the calibration circuit 120 is configured to initiate a calibration of the first oscillator 101 using the second oscillator 102 during manufacturing, for example, as part of a final test of a produced electronic device 100.

The example calibration circuit 120 in FIG. 1A includes an AND gate 125 with a first input connected to the first calibration circuit input 121 to receive the first clock output signal CLK1 from the first oscillator output 103. The output of the AND gate 125 is connected to an input of a first counter 126 (e.g., labeled “COUNTER 1”). During calibration operation, the first counter 126 counts the number of clock pulses from the output of the AND gate 125 and provides a corresponding first counter value D1NEW to a first counter output. The calibration circuit 120 in this example includes a second counter 127 with an input coupled to receive the second clock output signal CLK2 from the second oscillator output 104. The second counter 127 has an output that provides a second count value to a comparator circuit 128. The comparator circuit 128 has an output connected to the second input of the AND gate 125 and provides a logic high or “1” value to the AND gate while the second count value from the second counter 127 is less than a predetermined second count value D2.

As further shown in FIG. 1A, the memory 130 stores the calibration data 132. In one example, the calibration data 132 includes trim data 133, 134 and 135 for the first oscillator 101 as well as a calibration count value 136. In this example, the trim data includes the first trim value 133 (e.g., slope trim or ST) used in the most recent oscillator calibration to trim the frequency slope of the first oscillator 101, and the second trim value 134 (e.g., magnitude trim or MT) used to trim a frequency magnitude in the most recent calibration of the first oscillator 101. In one example, the first and second trim values 133 and 134 are digital values used by the trim controller 106 to set the respective amplifier gain and resistor value of the example current source trim circuit 110. In other implementations, different forms and types of trim values can be stored in the calibration data 132 of the memory 130. In these or other examples, the calibration data 132 can include a temperature independent trim value 135 for use to trim the frequency slope of the first oscillator 101. In the illustrated example, moreover, the calibration data 132 includes a count value 136 (e.g., labeled “D1” and representing a count of clock pulses from the first oscillator 102 in a predetermined duration during oscillator calibration.

In operation of the calibration circuit 120 during calibration, the AND gate 125 passes the first clock output signal CLK1 to the input of the first counter 126 until the second count value from the second counter 127 is less than D2. In this manner, the final first counter value D1NEW represents the number of clock cycles of the first clock output signal CLK1 during a predetermined duration represented by the value D2. The calibration circuit 120 includes a comparator 129 that compares the final first counter value D1NEW to the count value 136 (D1) obtained in the most recent calibration (e.g., labeled “D1OLD”) from the calibration data 132 in the memory 130. The output of the comparator 129 provides a count change value ΔD1 that represents the difference between the current calibration value D1NEW and the previous value D1OLD (e.g., =D1OLD−D1NEW). The count change value ΔD1 represents the amount of aging degradation of the first oscillator 102 with respect to the frequency and period TOSC1 of the first clock output signal CLK1.

In one example, the calibration circuit 120 provides the count change value ΔD1 to the trim controller 106, which obtains the previous trim values 133 (ST) and 134 (MT) from the memory 130 and adjusts one or both of these to compensate for the amount of clock frequency or period degradation represented by the count change value ΔD1. In this example, the trim controller 106 overwrites the respective trim values 133 and 134 in the memory 130 with the new values for ST and MT. In this example, the calibration controller 120 overwrites the count value 136 (D1) in the memory 130 with the most recent counter value, which corresponds to the trim changes made by the trim controller 106.

In another example, the calibration circuit 120 computes the updated values for the respective trim values 133 and 134 (e.g., ST and MT) based on the count change value ΔD1, and provides these updated values to the trim controller 106, which provides these at the respective trim outputs 107 and 108 to update the trim circuit 110 of the first oscillator 101. In this example, the calibration controller 120 overwrites the count value 136 (D1) in the memory 130 with the most recent counter value, which corresponds to the trim changes made by the trim controller 106.

The self-calibration features of the electronic device 100 can be used at any time, including manufacturing, such as trimming as part of final test, as well as in field use. The use of the second oscillator 102 to automatically calibrate the first oscillator 101 advantageously reduces the cost of oscillator production testing to trim the oscillator 101 after packaging to account for the impact of mechanical and/or thermal packaging stresses. In addition, the on-chip oscillator frequency measurement mitigates or avoids calibration dependency on precise external clock sources during final testing in a production setting. Moreover, the electronic device 100 can mitigate adverse effects of component ageing that can otherwise lead to frequency drift in the first oscillator 101.

Referring also to FIGS. 2-4, FIG. 2 shows an example method 200 of calibrating an oscillator of an electronic device, including calibration during manufacturing as well as subsequent field calibration. The method 200 includes a first calibration at 201 of the first oscillator 101 using the second oscillator 102 of the electronic device 100, for example, during manufacturing. In one example, the first calibration includes trimming one or more trim values of the first oscillator. At 202 in one implementation, multiple trims are used, including trimming both the frequency slope (slope trim value ST) and the frequency magnitude (magnitude trim value MT).

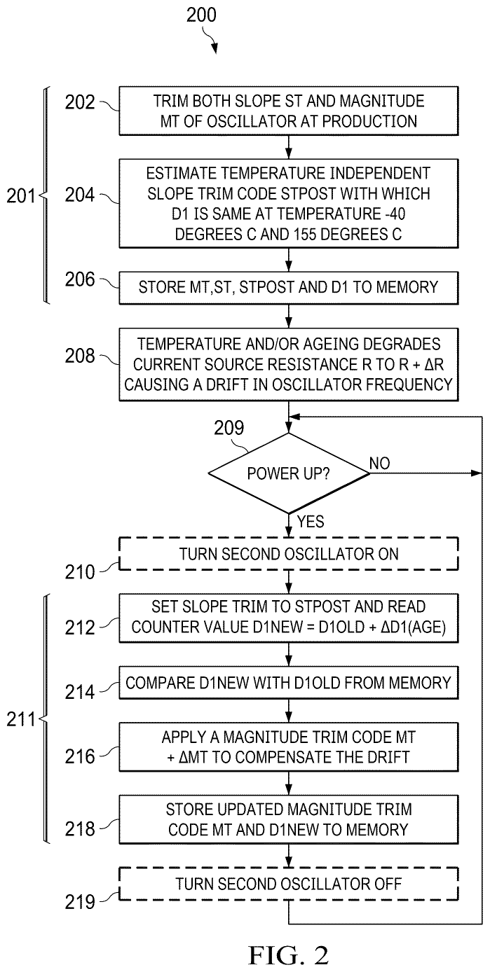

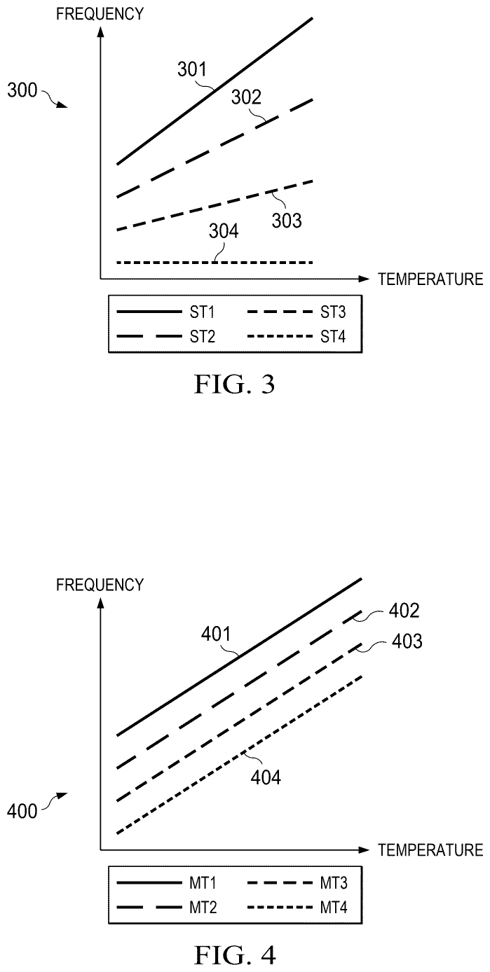

In one implementation, the factory calibration at 201 and associated trimming at 202 is performed at two or more different temperatures in production testing. FIG. 3 shows a graph 300 of example frequency slope trim values as a function of temperature, including a first slope trim value curve 301 (e.g., labeled “ST1”), a second slope trim value curve 302 (e.g., labeled “ST2”), a third slope trim value curve 303 (e.g., labeled “ST3”), and a fourth slope trim value curve 304 (e.g., labeled “ST4”). FIG. 4 shows a graph 400 of example frequency magnitude trim values as a function of temperature, including a first magnitude trim value curve 401 (e.g., labeled “MT1”), a second magnitude trim value curve 402 (e.g., labeled “MT2”), a third magnitude trim value curve 403 (e.g., labeled “MT3”), and a fourth magnitude trim value curve 404 (e.g., labeled “MT4”).

In one implementation, the factory calibration at 201 in FIG. 2 also includes estimating a temperature independent slope trim value (e.g., 135 “STPOST” in FIG. 1A), which can be used to trim the frequency slope of the first oscillator 101. In one example, this includes measuring the number of first oscillator pulses counted during a predetermined duration (e.g., duration D2 as described above) for a variety of different slope trim values at two or more different temperatures during manufacturing final testing (e.g., at −40 and +155 degrees C). The factory calibration at 201 in one example includes identifying the slope trim value ST for which the frequency is least affected by changing temperature (e.g., ST4, curve 304 in FIG. 3), and storing this value STPOST 135 in the calibration data 132 of the memory 130. In one example, the calibration circuit 120 is configured to use the estimated temperature independent STPOST slope trim value in performing a subsequent field calibration (e.g., instead of using the ST value 133 in FIG. 1A) to help mitigate any calibration accuracy variations associated with temperature to facilitate field calibration independent of the temperature during field calibration. In certain implementations, the temperature of the electronic device 100 may be unknown when field calibration is performed, and the use of an estimated temperature independent STPOST slope trim value 135 in calibrating the first oscillator 101 helps mitigate temperature effects. In another implementation, the temperature independent slope trim estimation at 204 in FIG. 2 can be omitted. The method 200 continues at 206 in FIG. 2 with storing the calibration data 132 from the first calibration in the memory 130 of the electronic device 100. In one example, the calibration circuit and/or the trim controller 106 write the calibration data 132 to the memory 130 to be available for the next field calibration (e.g., the next time the electronic device 100 is powered up).

The method 200 of FIG. 2 continues with field use at 208, with the passage of time and/or thermal stress to the electronic device 100 accumulating in field use (e.g., installed and operating in a host system to provide the clock signal CLK1 to the clocked circuit 109). The calibration controller 120 in one implementation continuously checks for detection of a device power up condition at 209 in FIG. 2. In one example, the electronic device 100 is operated in a normal or default mode with the second oscillator 102 turned off (e.g., with the calibration controller 120 in FIG. 1A providing the calibration enable signal CALEN at the output 123 to disable and deenergize the ring oscillator 140) until the calibration controller 120 detects a power up condition or event at 209 in FIG. 2. This mitigates or prevents age related degradation of the second oscillator 102 even as the first oscillator 101 is continuously powered for potentially long periods of time, and the method 200 remains at 209 in FIG. 2 while no power up condition has been detected (NO at 209). The degradation of the first oscillator 101 in one example can be attributed at least in part to thermal effects that change the resistance R of the example current source trim circuit resistor 115 in FIG. 1A. Due to baking or other thermal processing during manufacturing or in service in a field installation, the resistance R can change (e.g., degraded to R+ΔR), which can lead to a drift in the period TOSC1 and the oscillator frequency (e.g., 1/TOSC1).

Once the electronic device 100 is powered up (YES at 209 in FIG. 2), the calibration controller 120 detects the power up condition or event and begins performing a second or subsequent calibration of the first oscillator 101 at 211 in FIG. 2 using the second oscillator 102 of the electronic device 100 and the calibration data 132 from the memory 130 in response to the electronic device 100 powering up. In one example, the calibration controller optionally turns the second oscillator 102 on (e.g., at 210 in FIG. 2) in response to the detected power up event or condition, prior to performing the second calibration at 211. In another implementation, the second oscillator 102 can be turned on separately or can remain on always, and the processing at 210 can be omitted in FIG. 2.

In one example, the second calibration at 211 in FIG. 2 includes setting the slope trim at 212. In one example, the calibration controller 120 or the trim controller 106 in FIG. 1A obtains the calibration data 132 from the memory 130, for example, one or more of the most recently updated slope trim value 133 (ST) or the estimated temperature independent slope trim value 135 (STPOST), the duration, value D1 (e.g., used as D1OLD for the current oscillator calibration), and/or the magnitude trim value 134 (MT). In one example, at 212 in FIG. 2, the trim controller 106 sets the slope trim to the estimated temperature independent slope trim value 135 (STPOST), for example, by providing a digital value at the first trim output 107 to set the amplifier gain of the amplifier 116 of the current source trim circuit 110 in FIG. 1A. In this or another example, the calibration circuit 120 operates the counters 126 and 127 and the comparator 129 to read the final (new), value D1NEW from the first counter 126.

At 214 in FIG. 2, the calibration circuit 120 uses the comparator 129 to compare D1NEW to D1OLD from the memory 130. In this example, the output of the comparator 129 indicates the count difference ΔD1 that is related to aging degradation of the first oscillator 101 (e.g., D1NEW=D1OLD+ΔD1). The age related oscillator degradation results in a shift or change in the output frequency (e.g., 1/TOSC1) of the first clock signal CLK1 at the first oscillator output 103.

At 216 in FIG. 2, in one example, the calibration circuit 120 causes the trim controller 106 to apply an adjusted magnitude trim code MT at the second output 108 to adjust the resistor value R of the resistor 115 in the current source trim circuit 110. In one example, the new magnitude trim value is the old magnitude trim value 134 (MT) from the memory 130 plus a magnitude change value ΔMT, for example, where ΔMT=the magnitude trim value 134 times the ratio of the new and old count values (ΔMT=MT*D1NEW/D1OLD) in order to compensate for the frequency shift determined by the comparator 129.

At 218 in FIG. 2, the calibration circuit 120 and/or the trim controller 106 store the updated values to the memory 130. In one example, the calibration circuit 120 includes logic or processing circuitry (not shown) that computes various adjusted and/or updated values based on the calibration data and the results from the most recent calibration (e.g., the comparator output) and stores one or more of the updated values 133-136 to the calibration data 132 of the memory 130. In one implementation, the calibration circuit 120 stores the updated magnitude trim code 134 (MT) and the new calibration counter value 136 (D1NEW) to the calibration data 132 of the memory 130 at 218 in FIG. 2.

In one example, the calibration circuit 120 turns the second oscillator 102 off at 219 in FIG. 2. As discussed above, this conserves power during normal operation of the electronic device 100 and also mitigates aging or other degradation effects on the second oscillator 102. This feature facilitates preservation of the second oscillator 102 as a good calibration reference for calibrating the first oscillator 101 during the service lifetime of the electronic device 100. As discussed above, and one example, the calibration circuit 120 turns on the second oscillator 102 in response to each new power up event of the electronic device 100, performs a calibration of the first oscillator 101 using the calibration data 132 from the memory 130 and the second oscillator 102 as a reference, stores updated values in the memory 130, and then turns the second oscillator 102 off at 219. In another implementation, the second oscillator 102 can be continuously operated, and the processing at 219 can be omitted.

The method 200 in FIG. 2 then returns to normal operation with the calibration circuit 120 checking for subsequent power up conditions or events at 209. Continued operation of the electronic device 100 over long periods of time can subject the first oscillator 101 to further degradation through ageing effects that can cause output frequency drift. The self-calibration features allow the device 100 to adapt to changes in the oscillator frequency. In one example, the calibration circuit 120 self-calibrates the first oscillator 101 using the second oscillator 102 in response to device power up events, with the second oscillator 102 powered down between calibrations. In other implementations, the self-calibration can be done at other times, such as periodically, according to a schedule, in response to power up or other events or device conditions, and/or in response to a user input, etc. or combinations thereof.

In various implementations, the calibration circuit 120 and/or the trim controller 106 can set or adjust one or both of the slope trim and/or the magnitude trim at the respective trim outputs 107 and 108 and store updated calibration data 132 to the memory 130 for subsequent operation of the first oscillator 101 in the electronic device 100 until the next oscillator calibration. The use in certain examples of the estimated temperature independent slope trim 135 (STPOST) advantageously makes the field calibration independent of the current temperature at which the electronic device 100 operates, for example, allowing adjustment of only the magnitude trim MT. This allows more extensive initial calibration of the first oscillator 101 during manufacturing at multiple temperatures to estimate the temperature independent slope trim 135, with the subsequent field calibration(s) at a single current temperature to accommodate device usage in a variety of different environmental conditions while maintaining calibration accuracy of the first clock signal CLK1 over time. In one example, to help calibration accuracy independent of the device temperature during field calibration, the calibration circuit 120 can use the temperature independent slope trim value 135 (STPOST) that was previously estimated and stored in the memory 130 during device manufacturing. In one example, the slope trim value 133 (ST) is a slope calibration code that compensates the temperature-frequency slope of the first oscillator 101, and the calibration circuit 120 and the trim controller 106 apply the slope trim value 133 to the first trim input 111 throughout the normal operation of the first oscillator 101 via the first output 107. The temperature independent slope trim value 135 (STPOST) can be used to compensate the combined frequency slope of the first and second oscillators 101 and 102, for example, during the second or subsequent field calibration of the first oscillator 101 using the second oscillator 102 while the trim controller 106 applies the temperature independent slope trim value 135 (STPOST) at the trim output 107 to help ensure that the estimated new count result (D1NEW) does not vary with change in field temperature and hence D1NEW is dependent on resistor drift alone. In this example, once the field calibration is done (e.g., at 219 in FIG. 2), the second oscillator can be powered off and the trim controller 106 again applies the slope trim value 133 at the output 107 for normal operation of the first oscillator 101. Moreover, the use of the integrated on-chip second oscillator 102 avoids the need for external calibration sources, which reduces the time, cost and complexity of initial calibration during manufacturing and greatly facilitates subsequent self-calibration of the first oscillator 101 in field installations.

In one example, the initial or first calibration of the first oscillator 101 can be done using the integrated second oscillator 102 after packaging or prior to packaging, such as during wafer probe testing, and the initial duration count D1 and other calibration data 132 can be stored in the memory 130 during wafer probe testing. A second production self-calibration of the first oscillator 101 can be performed after packaging using the calibration data 132 and the second oscillator 102, for example, to accommodate thermal and/or mechanical stresses that affect the first oscillator 101. In these examples, no external calibration clock sources are needed, which can significantly reduce production time and cost, while providing calibration data 132 for use and updating thereafter in subsequent oscillator calibrations in the field.

The use of a ring type second oscillator 102 advantageously helps calibration accuracy, where CMOS delay line aging is significantly less than resistor aging, even if the second oscillator 102 remains enabled during normal operation of the electronic device 100. In certain examples, the second oscillator 102 is selectively turned off between oscillator calibrations, which can significantly mitigate CMOS delay aging to ensure the second oscillator 102 provides a repeatable reference for calibrating the first oscillator 101 and also reduces power consumption of the electronic device 100 during normal operation.

These and other advantages of the described examples can improve operation of the electronic device 100 and any clocked circuits 109 that use the clock output signal CLK1 to provide low frequency variation across process, voltage and temperature (PVT), as well as controlling oscillator frequency variation of the service lifetime of the electronic device 100.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a first oscillator having a trim input and a first oscillator output;
a second oscillator having a second oscillator output;
a memory that stores calibration data; and
a calibration circuit coupled to the first and second oscillator outputs and configured to automatically calibrate the first oscillator using the second oscillator based on the calibration data.

2. The electronic device of claim 1, wherein the calibration circuit is configured to calibrate the first oscillator in response to the electronic device powering up.

3. The electronic device of claim 2, wherein the calibration circuit is configured to automatically turn the second oscillator off after calibrating the first oscillator.

4. The electronic device of claim 1, wherein the calibration data includes trim data for the first oscillator and a calibration count value.

5. The electronic device of claim 4, wherein the trim data includes a first trim value to trim a frequency slope of the first oscillator, and a second trim value to trim a frequency magnitude of the first oscillator.

6. The electronic device of claim 1, wherein the calibration data includes a temperature independent trim value to trim a frequency slope of the first oscillator.

7. The electronic device of claim 6, wherein the calibration circuit uses the temperature independent trim value to automatically calibrate the first oscillator using the second oscillator.

8. The electronic device of claim 1, wherein the calibration circuit is configured to automatically turn the second oscillator off after calibrating the first oscillator.

9. The electronic device of claim 1, wherein the second oscillator is a ring oscillator.

10. An electronic device, comprising:
a first oscillator having a first trim input, a second trim input and a first oscillator output;
a second oscillator having a second oscillator output;
a calibration circuit coupled to the first and second oscillator outputs;
a trim controller having a first trim output coupled to the first trim input, and a second trim output coupled to the second trim input; and
a memory that stores calibration data from a factory calibration of the first oscillator.

11. The electronic device of claim 10, wherein the calibration circuit is configured to calibrate the first oscillator in response to the electronic device powering up.

12. The electronic device of claim 10, wherein the calibration circuit is configured to automatically turn the second oscillator off after calibrating the first oscillator.

13. The electronic device of claim 10, wherein the calibration data includes trim data for the first oscillator and a calibration count value.

14. The electronic device of claim 13, wherein the trim data includes a first trim value to trim a frequency slope of the first oscillator, and a second trim value to trim a frequency magnitude of the first oscillator.

15. The electronic device of claim 10, wherein the calibration data includes a temperature independent trim value to trim a frequency slope of the first oscillator.

16. The electronic device of claim 10, wherein the second oscillator is a ring oscillator.

17. The electronic device of claim 10, wherein the first oscillator includes a current source trim circuit having the first trim input to set an amplifier gain to trim a frequency slope of the first oscillator and the second trim input to set a resistor value to trim a frequency magnitude of the first oscillator.

18. A method, comprising:
performing a first calibration of a first oscillator of an electronic device using a second oscillator of the electronic device; and
storing calibration data from the first calibration in a memory of the electronic device.

19. The method of claim 18, further comprising:
performing a second calibration of the first oscillator using the second oscillator of the electronic device and the calibration data from the memory; and
storing updated calibration data from the second calibration in the memory.

20. The method of claim 19, comprising performing the second calibration in response to the electronic device powering up.

21. The method of claim 19, further comprising:
turning the second oscillator on before performing the second calibration; and
turning the second oscillator off after performing the second calibration.

22. A system, comprising:
a clocked circuit having a clock input; and
an electronic device, comprising:
a first oscillator having a first trim input, a second trim input and a first oscillator output coupled to the clock input of the clocked circuit;
a second oscillator having a second oscillator output;
a calibration circuit coupled to the first and second oscillator outputs;
a trim controller having a first trim output coupled to the first trim input, and a second trim output coupled to the second trim input; and
a memory that stores calibration data from a factory calibration of the first oscillator.

23. The system of claim 22, wherein the calibration circuit is configured to automatically turn the second oscillator off after calibrating the first oscillator.

24. The system of claim 22, wherein the calibration data includes trim data for the first oscillator and a calibration count value.

25. The system of claim 22, wherein the calibration data includes a temperature independent trim value to trim a frequency slope of the first oscillator.
